(19) United States
(12) Patent Application Publication
(10) Pub. No.: US 2023/0282618 A1
(43) Pub. Date: Sep. 7, 2023

(54) SEMICONDUCTOR DEVICE AND METHOD FOR MANUFACTURING SAME

(71) Applicant: UltraMemory Inc., Tokyo (JP)

(72) Inventors: Ichiro HOMMA, Tokyo (JP); Tsuyoshi KAWAGOE, Tokyo (JP)

(21) Appl. No.: 18/005,292

(22) PCT Filed: Jul. 16, 2020
(86) PCT No.: PCT/JP2020/027728

§ 371 Date: Jan. 12, 2023

(51) Int. Cl. H01L 25/065; H01L 21/768; H01L 23/00

(52) U.S. Cl. CPC H01L 25/0657; H01L 21/76898; H01L 24/32; H01L 24/83; H01L 2224/32145; H01L 2224/8393; H01L 2225/06544; H01L 2225/06565

(57) ABSTRACT

A semiconductor device is provided with: a reference unit in which at least two circuit modules are stacked with circuit layers adjoining each other; an additional unit in which at least two other circuit modules are stacked with circuit layers adjoining each other, the additional unit being stacked on the reference unit; and a via disposed through the reference unit and the additional unit and extending in a stacking direction. The via includes a reference via disposed in the reference unit, and an additional via disposed in the additional unit. The additional via at the position of contact with the reference via has a diameter smaller than a diameter of the reference via.

### TECHNICAL FIELD

The present invention relates to a semiconductor device and a method for manufacturing the semiconductor device.

### BACKGROUND ART

Typically, a volatile memory (RAM) such as a dynamic random access memory (DRAM) has been known as a storage device. DRAMs are required to have a high capacity to withstand the increasing performance of arithmetic devices (hereinafter referred to as logic chips) and the increasing volume of data. For this reason, such a high capacity has been achieved by memory (a memory cell array, a memory chip) miniaturization and two-dimensional additional cell installation. Meanwhile, the high capacity of this type has reached the limit thereof due to vulnerability to noise due to miniaturization, a die area increase, etc.

For these reasons, a technique of achieving the high capacity in such a manner that a plurality of planar memories are stacked three-dimensionally (three-dimensionalization) has been recently developed. A semiconductor module in which a plurality of modules stacked on each other is electrically connected to each other has been proposed (see, e.g., Patent Documents 1 and 2).

Patent Document 1: Japanese Unexamined Patent Application, Publication No. 2016-46447
Patent Document 2: Japanese Unexamined Patent Application, Publication No. 2012-227328

### DISCLOSURE OF THE INVENTION

### Problems to be Solved by the Invention

In a semiconductor module formation method of Patent Document 1, a through-hole penetrating the semiconductor module from an electrode in an uppermost layer to an electrode surface in a lowermost layer is formed. In Patent Document 1, when the through-hole is formed by etching, the electrodes in the uppermost and intermediate layers function as a hard mask. For this reason, an electrode in an upper layer is exposed to etching for a longer time. Thus, the electrode in the upper layer is damaged and thinned. Particularly, there is a problem that the damage on the electrode increases as the number of stacked layers increases. Moreover, the opening diameter of the uppermost layer increases as the number of stacked layers increases. For these reasons, the area of a through-hole electrode region increases.

The semiconductor module disclosed in Patent Document 2 is configured such that three modules are stacked on a support substrate. A through-hole electrode is arranged for every two adjacent modules. The modules are electrically connected to each other through the plurality of through-hole electrodes, and in this manner, wiring layers of three modules are connected to each other. In a step of forming the plurality of through-hole electrodes, the plurality of through-hole electrodes are formed exclusively in order. For this reason, a long time is necessary for the through-hole electrode formation step, leading to a higher manufacturing cost. Moreover, in Patent Document 2, the through-hole electrodes with different openings are used for different layers, and for this reason, the number of openings increases as the number of stacked layer increases, and the area of a through-hole electrode region increases accordingly.

The present invention is intended to provide a semiconductor device and a method for manufacturing the semiconductor device so that an increase in the area of a through-hole electrode region can be suppressed.

### Means for Solving the Problems

The present invention relates to a semiconductor device in which a plurality of circuit modules each having a circuit layer and a substrate body are stacked on each other. The semiconductor device includes a reference unit in which at least two circuit modules are stacked on each other with the circuit layers adjacent to each other; an additional unit in which at least two other circuit modules are stacked on each other with the circuit layers adjacent to each other, the additional unit being stacked on the reference unit; and a via arranged so as to extend through the reference unit and the additional unit and extending in a stacking direction. The via has a reference via arranged in the reference unit, and an additional via arranged in the additional unit. The additional via has, at a position at which the additional via contacts the reference via, a smaller diameter than the diameter of the reference via.

The additional via may have an additional via body penetrating the additional unit in the stacking direction, and an additional barrier metal contacting an outer peripheral surface of the additional via body and contacting the reference via.

The reference via may extend from a surface of the reference unit stacked on the additional unit along the stacking direction while the diameter of the reference via is narrowed.

A tip end portion of the reference via may extend to the circuit layer of one of the circuit modules which is different from the other circuit module contacting the additional unit.

The additional unit may include a plurality of additional units stacked on the reference unit.

The substrate body of each circuit module may have a dielectric film surrounding the reference via or the additional via and extending along the stacking direction.

The present invention relates to a method for manufacturing a semiconductor device in which a plurality of circuit modules each having a circuit layer and a substrate body are stacked on each other. The method includes a reference unit formation step of forming a reference unit in which at least two circuit modules are stacked on each other with the circuit layers adjacent to each other, a reference via formation step of forming, inside the reference unit, a reference via extending in a stacking direction of the reference unit, an additional unit formation step of forming an additional unit by stacking at least two other circuit modules on each other with the circuit layers adjacent to each other, a stacking step of stacking the additional unit on the reference unit, and an additional via formation step of forming an additional via extending in a stacking direction of the additional unit and penetrating the additional unit to contact the reference via.

In the method for manufacturing the semiconductor device, the reference unit formation step further may include a first dielectric film formation step of forming a dielectric film in the substrate body of each circuit module of the reference unit, the dielectric film being formed so as to surround a position at which the reference via is to be formed; and the additional unit formation step further may include a second dielectric film formation step of forming a dielectric film in the substrate body of each circuit module of the additional unit, the dielectric film being formed so as to surround a position at which the additional via is to be formed.

### Effects of the Invention

According to the present invention, the semiconductor device and the method for manufacturing the semiconductor device can be provided so that an increase in the area of the through-hole electrode region can be suppressed.

### BRIEF DESCRIPTION OF THE DRAWINGS

FIG. 1 is a sectional view showing a semiconductor device according to a first embodiment of the present invention;

FIG. 2 is a sectional view showing a process for manufacturing the semiconductor device of the first embodiment;

FIG. 3 is a sectional view showing the process for manufacturing the semiconductor device of the first embodiment;

FIG. 4 is a sectional view showing the process for manufacturing the semiconductor device of the first embodiment;

FIG. 5 is a sectional view showing the process for manufacturing the semiconductor device of the first embodiment;

FIG. 6 is a sectional view showing the process for manufacturing the semiconductor device of the first embodiment;

FIG. 7 is a sectional view showing the process for manufacturing the semiconductor device of the first embodiment;

FIG. 8 is a sectional view showing the process for manufacturing the semiconductor device of the first embodiment;

FIG. 9 is a sectional view showing the process for manufacturing the semiconductor device of the first embodiment;

FIG. 10 is a sectional view showing the process for manufacturing the semiconductor device of the first embodiment;

FIG. 11 is a sectional view showing a semiconductor device according to a second embodiment of the present invention;

FIG. 12 is a sectional view showing a process for manufacturing the semiconductor device of the second embodiment;

FIG. 13 is a sectional view showing the process for manufacturing the semiconductor device of the second embodiment;

FIG. 14 is a sectional view showing the process for manufacturing the semiconductor device of the second embodiment;

FIG. 15 is a sectional view showing the process for manufacturing the semiconductor device of the second embodiment; and

FIG. 16 is a sectional view showing the process for manufacturing the semiconductor device of the second embodiment.

### PREFERRED MODE FOR CARRYING OUT THE INVENTION

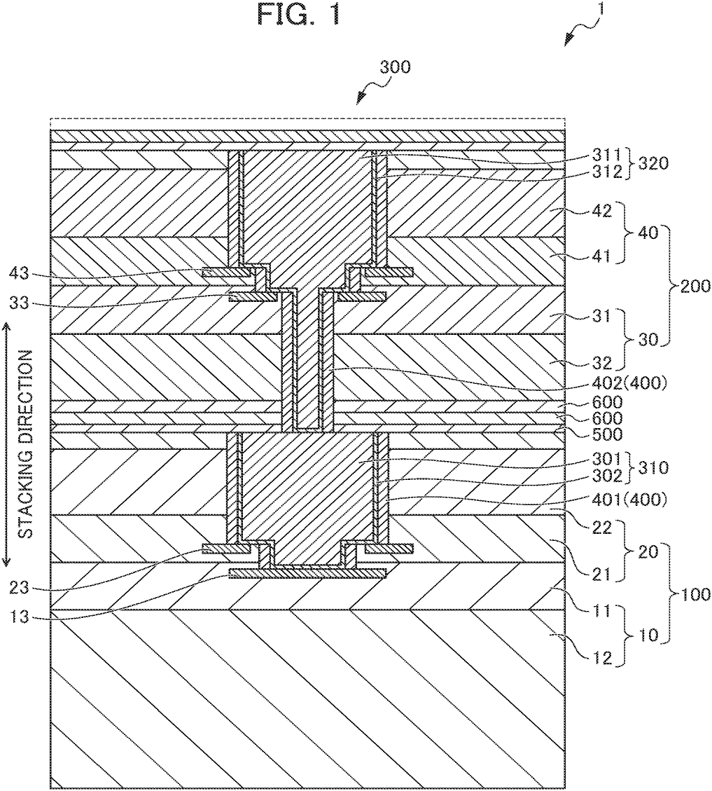

Hereinafter, a semiconductor device 1 and a method for manufacturing the semiconductor device 1 according to each embodiment of the present invention will be described with reference to FIGS. 1 to 16. The semiconductor device 1 according to each embodiment is, for example, a memory module, and is configured such that a plurality of circuit modules 10, 20, 30, 40 (RAMs) are stacked on an interface module (e.g., an active interposer (AIP)). The interface module is also one example of the circuit module. A configuration without an interface module is also one example of the memory module. In the semiconductor device 1 according to each embodiment, the plurality of circuit modules 10, 20, 30, 40 are electrically connected to each other through a through-hole electrode (via). The circuit module 10, 20, 30, 40 includes a circuit layer 11, 21, 31, 41 and a substrate body 12, 22, 32, 42.

The circuit layer 11, 21, 31, 41 is, for example, a silicon dioxide (SiO₂) layer. The circuit layer 11, 21, 31, 41 has an electrode inside. The circuit layer 11, 21, 31, 41 has, for example, an electrode 13, 23, 33, 43 contacting the through-hole electrode.

The electrode 13, 23, 33, 43 is, for example, a plate-shaped body extending in a direction crossing a stacking direction of the circuit layers 11, 21, 31, 41. The electrode 13, 23, 33, 43 is arranged with the position thereof aligned with the position of the through-hole electrode.

Specifically, the electrode 13, 23, 33, 43 is arranged at such a position that the electrode 13, 23, 33, 43 contacts an outer peripheral surface of the through-hole electrode. In the embodiments below, the electrode 13, 23, 33, 43 arranged at one end in the stacking direction is provided as a plate-shaped body having no through-hole, for example. The electrode 13, 23, 33, 43 arranged at a position other than one end in the stacking direction is provided as a plate-shaped body having a through-hole with a predetermined size, for example. Particularly, in the embodiments below, one, which is arranged on one end side in the stacking direction, of the electrodes 13, 23, 33, 43 arranged in adjacent ones of the circuit layers 11, 21, 31, 41 has a through-hole with a smaller diameter than that of the other one of the electrodes 13, 23, 33, 43 arranged on the other end side.

The substrate body 12, 22, 32, 42 is, for example, a silicon (Si) layer. The substrate body 12, 22, 32, 42 is arranged adjacent to one surface side of the circuit layer 11, 21, 31, 41. In the embodiments below, the substrate body 12, 22, 32, 42 of the circuit module 10, 20, 30, 40 at one end in the stacking direction is formed thicker than those of the other circuit modules 10, 20, 30, 40.

The semiconductor device 1 according to each embodiment below is configured such that the diameter of the through-hole electrode is a predetermined diameter or less. With this configuration, the area of the through-hole electrode with respect to the surface of the circuit module 10, 20, 30, 40 can be reduced. Specifically, the semiconductor device 1 is configured such that the diameter of the through-hole electrode is the predetermined diameter or less in such a manner that a plurality of through-hole electrodes having sections in a raised shape is arranged in the stacking direction.

### First Embodiment

Next, a semiconductor module and a method for manufacturing the semiconductor module according to a first embodiment of the present invention will be described with reference to FIGS. 1 to 10. A semiconductor device 1 according to the present embodiment has such a structure that a plurality of circuit modules 10, 20, 30, 40 having circuit layers 11, 21, 31, 41 and substrate bodies 12, 22, 32, 42 are stacked on each other. The semiconductor device 1 has, for example, such a structure that four circuit modules 10, 20, 30, 40 are stacked on each other. The semiconductor device 1 includes a reference unit 100, an additional unit 200, a via 300, and an insulating film 400. Note that a direction from the additional unit 200 to the reference unit 100 in FIG. 1 will be described as one end side in a stacking direction. Moreover, the opposite side will be described as the other end side.

The reference unit 100 has such a structure that the plurality of circuit modules 10, 20 are stacked on each other with the circuit layers 11, 21 adjacent to each other. In the present embodiment, the reference unit 100 has, for example, such a configuration that the circuit layers 11, 21 of two circuit modules 10, 20 are bonded to each other with the positions of electrodes 13, 23 aligned with each other. Moreover, the reference unit 100 is configured such that the outer diameter of the electrode 13 of the circuit module 10 on one end side in the stacking direction is larger than a through-hole of the electrode 23 of the circuit module 20 on the other end side. More specifically, the reference unit 100 is arranged such that the electrode 23 of the circuit module 20 on the other end side in the stacking direction overlaps with an outer peripheral portion of the electrode 13 of the circuit module 10 on one end side in the stacking direction. Further, the reference unit 100 is configured such that a substrate body 12 of the circuit module 10 on one end side in the stacking direction is thicker than a substrate body 22 of the circuit module 20 on the other end side.

The additional unit 200 is configured such that two other circuit modules 30, 40 are stacked on each other with the circuit layers 31, 41 adjacent to each other, and is stacked on the reference unit 100. As in the reference unit 100, the additional unit 200 has, for example, such a configuration that the circuit layers 31, 41 of two circuit modules 30, 40 are bonded to each other with the positions of electrodes 33, 43 aligned with each other. The additional unit 200 is stacked on the other-end-side circuit module 20 of the reference unit 100 in the stacking direction. Moreover, the additional unit 200 is configured such that the outer diameter of the electrode 33 of the circuit module 30 on one end side in the stacking direction is larger than a through-hole of the electrode 43 of the circuit module 40 on the other end side. More specifically, the additional unit 200 is arranged such that the electrode 43 of the circuit module 40 on the other end side in the stacking direction overlaps with an outer peripheral portion of the electrode 33 of the circuit module 30 on one end side in the stacking direction. Further, the additional unit 200 is configured such that the electrode 33 of the circuit module 30 on one end side in the stacking direction has a smaller through-hole than the through-hole of the electrode 43 of the circuit module 40 on the other end side.

The via 300 is arranged so as to extend through the reference unit 100 and the additional unit 200, and extends in the stacking direction. In the present embodiment, the via 300 is configured such that large-diameter portions and small-diameter portions are alternately repeatedly formed along the stacking direction. The via 300 includes a reference via 310 and an additional via 320.

The reference via 310 is arranged in the reference unit 100. The reference via 310 extends, along the stacking direction, from an end surface of the circuit module 20 on the other end side in the stacking direction to a position at which the reference via 310 contacts the electrode 13 of the circuit module 10 on one end side, for example. The reference via 310 extends from the surface of the reference unit 100 stacked on the additional unit 200 along the stacking direction while the diameter of the reference via 310 is narrowed. A tip end portion of the reference via 310 extends to the electrode 13 of the circuit module 10 which is different from the other circuit module 20 contacting the additional unit 200. The reference via 310 includes a reference via body 301 and a reference barrier metal 302.

The reference via body 301 is, for example, made of copper (Cu). In the present embodiment, the reference via body 301 has a section raised toward one end in the stacking direction. The reference via body 301 faces, at the large-diameter portion, the other-end-side surface of the electrode 23 of the circuit module 20 on the other end side in the stacking direction. Moreover, the reference via body 301 penetrates, at the large-diameter portion, the electrode 23 of the circuit module 20 on the other end side in the stacking direction. Further, the reference via body 301 faces, at the small-diameter portion, the other-end-side surface of the electrode 13 of the circuit module 10 on one end side in the stacking direction.

The reference barrier metal 302 is, for example, made of tantalum nitride (TaN), tantalum (Ta), or a multilayer film thereof. The reference barrier metal 302 is arranged between the reference via body 301 and the reference unit 100. The reference barrier metal 302 is arranged in contact with an outer peripheral surface of the reference via body 301 other than a surface on the other end side in the stacking direction.

The additional via 320 is arranged in the additional unit 200. The additional via 320 penetrates, along the stacking direction, the additional unit 200 from an end surface of the circuit module 40 on the other end side in the stacking direction to an end surface of the circuit module 30 on one end side, for example. Moreover, the additional via 320 contacts, at one end in the stacking direction, the other end of the reference via 310. The additional via 320 has, at a position at which the additional via 320 contacts the reference via 310, a smaller diameter than the diameter of the reference via 310. The additional via 320 includes an additional via body 311 and an additional barrier metal 312.

The additional via body 311 is, for example, made of copper (Cu). The additional via body 311 penetrates the additional unit 200 in the stacking direction. In the present embodiment, the additional via body 311 has a section raised toward one end in the stacking direction. The additional via body 311 faces, at the large-diameter portion, the other-end-side surface of the electrode 43 of the circuit module 40 on the other end side in the stacking direction. Moreover, the additional via body 311 penetrates, at the first small-diameter portion, the electrode 43 of the circuit module 40 on the other end side in the stacking direction. Further, the additional via body 311 faces, at the first small-diameter portion, the other-end-side surface of the electrode 33 of the circuit module 30 on one end side in the stacking direction. In addition, the additional via body 311 penetrates, at the second small-diameter portion having a smaller diameter than that of the first small-diameter portion, the electrode 33 of the circuit module 30 on one end side in the stacking direction.

The additional barrier metal 312 is, for example, made of tantalum nitride (TaN), tantalum (Ta), or a multilayer film thereof. The additional barrier metal 312 contacts not only an outer peripheral surface of the additional via body 311, but also the reference via 310. The additional barrier metal 312 is, for example, arranged between the additional via body 311 and the additional unit 200. The additional barrier metal 312 is arranged in contact with an outer peripheral surface of the additional via body 311 other than a surface on the other end side in the stacking direction. That is, the additional barrier metal 312 is sandwiched between the reference via body 301 and the additional via body 311.

The insulating film 400 is arranged between the reference via 310 and the reference unit 100. Moreover, the insulating film 400 is arranged between the additional via 320 and the additional unit 200. The insulating film 400 includes a reference-side insulating film 401 and an additional-side insulating film 402.

The reference-side insulating film 401 is, for example, made of silicon dioxide (SiO₂). The reference-side insulating film 401 is arranged in contact with a surface of the reference barrier metal 302 crossing the stacking direction.

The additional-side insulating film 402 is, for example, made of silicon dioxide (SiO₂). The additional-side insulating film 402 is arranged in contact with a surface of the additional barrier metal 312 crossing the stacking direction.

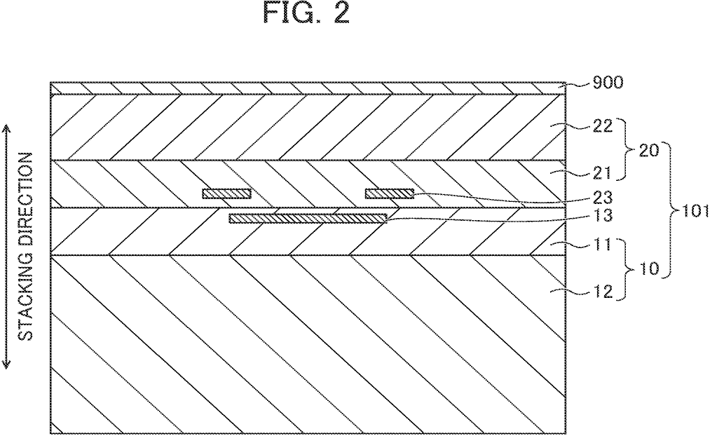

Next, the method for manufacturing the semiconductor device 1 of the first embodiment will be described with reference to FIGS. 2 to 10. The method for manufacturing the semiconductor device 1 includes a reference unit formation step, a reference via formation step, an additional unit formation step, a stacking step, and an additional via formation step.

In the reference unit formation step, two circuit modules 10, 20 are stacked on each other with the circuit layers 11, 21 adjacent to each other, and in this manner, the reference unit 100 is formed as shown in FIG. 2. In the reference unit formation step, the substrate body 22 of the circuit module 20 on the other end side in the stacking direction is ground after stacking, and a protective film 900 is arranged on the ground surface. The protective film 900 is, for example, made of silicon dioxide (SiO₂).

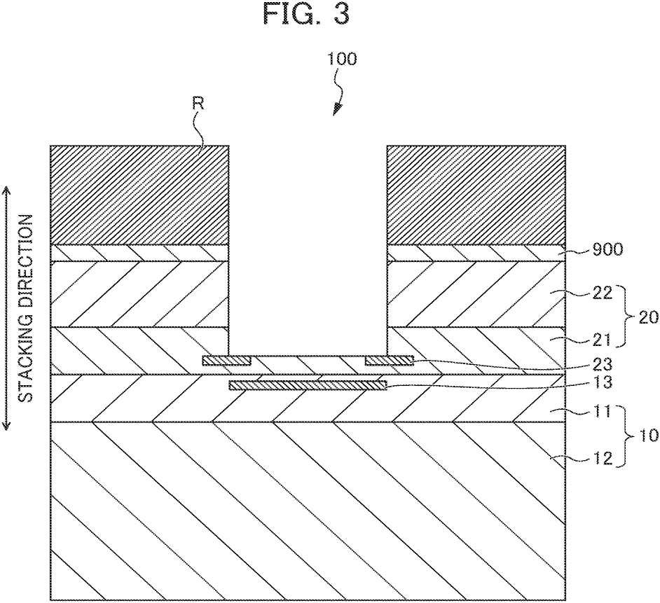

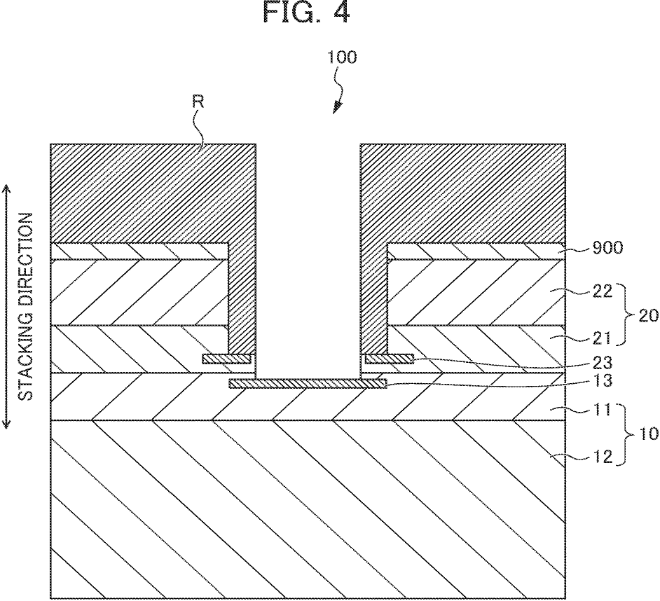

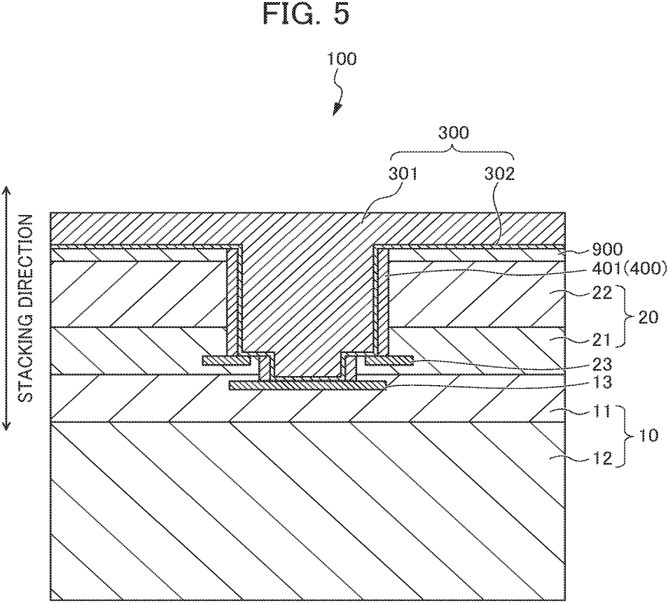

Subsequently, the reference via formation step is executed. In the reference via formation step, the reference via 310 extending in the stacking direction of the reference unit 100 is formed inside the reference unit 100. First, in the reference via formation step, anisotropic etching is performed using resist R, and in this manner, a via hole is formed with the position thereof aligned with the position of the electrode 23 of the circuit module 20 on the other end side in the stacking direction, as shown in FIG. 3. Subsequently, in the reference via formation step, a via hole is formed with the position thereof aligned with the position of the through-hole of the electrode 23 of the circuit module 20 on the other end side in the stacking direction, as shown in FIG. 4. Subsequently, in the reference via formation step, the reference-side insulating film 401, the reference barrier metal 302, and the reference via body 301 are formed at the position of the via hole, as shown in FIG. 5.

Subsequently, the additional unit formation step is executed. In the additional unit formation step, two other circuit modules 30, 40 are stacked on each other with the circuit layers 31, 41 adjacent to each other, and in this manner, the additional unit 200 is formed. In the additional unit formation step, the substrate body 32 of the circuit module 30 on the side on which the circuit module 30 is to be stacked on the reference unit 100 is ground in the stacking direction, and a cross-linked layer 600 as an adhesive is formed on the ground surface.

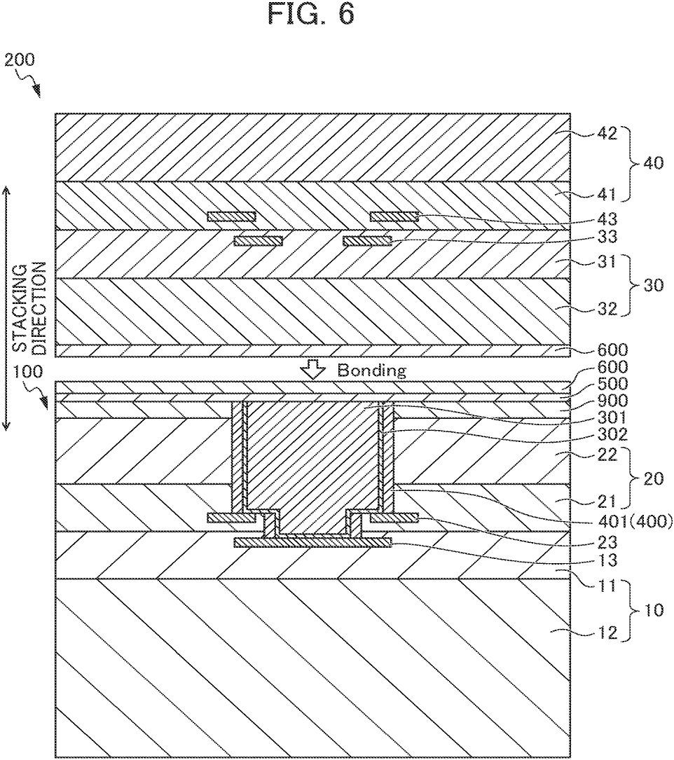

Subsequently, the stacking step is executed. In the stacking step, the additional unit 200 is stacked on the reference unit 100. In the stacking step, the additional unit 200 is stacked with the position thereof aligned with the position of each electrode 13, 23 of the reference unit 100, as shown in FIG. 6. Moreover, in the stacking step, after the additional unit 200 has been stacked on the reference unit 100, the substrate body 42 of the additional unit 200 on the other end side in the stacking direction is ground in the stacking direction, and a protective film 900 is arranged on the ground surface. Note that in the stacking step in the present embodiment, an etching stop layer 500 and the cross-linked layer 600 as the adhesive are formed on the surface of the reference unit 100 facing the additional unit 200 before stacking.

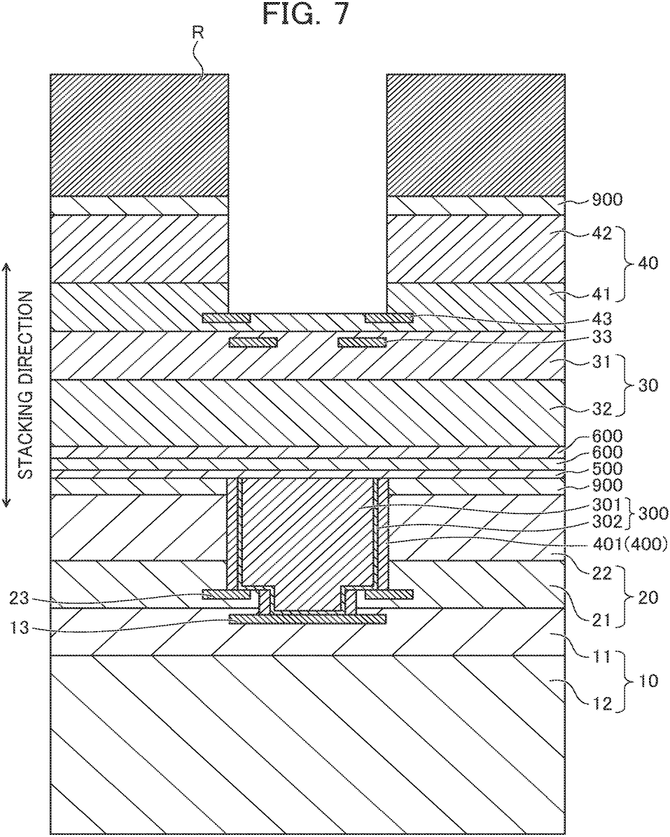

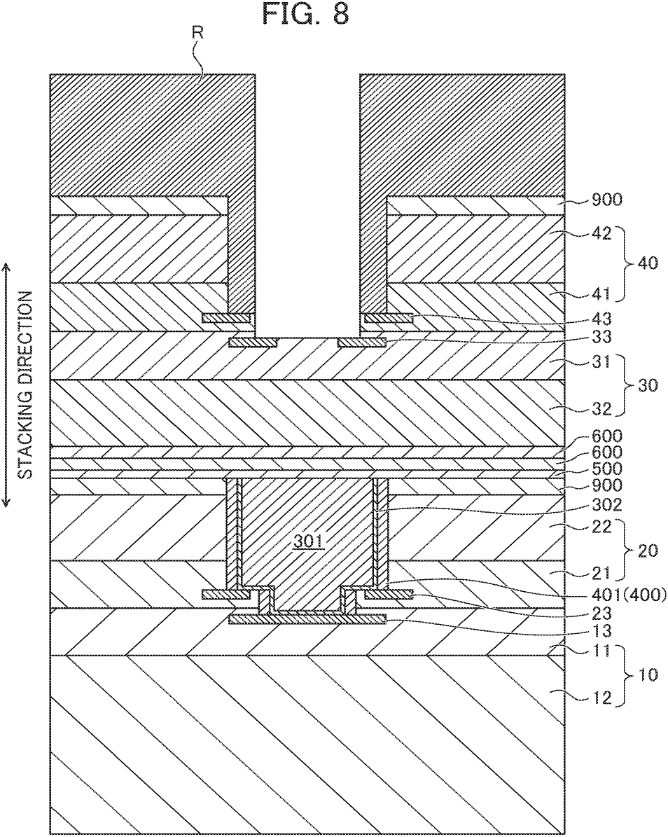

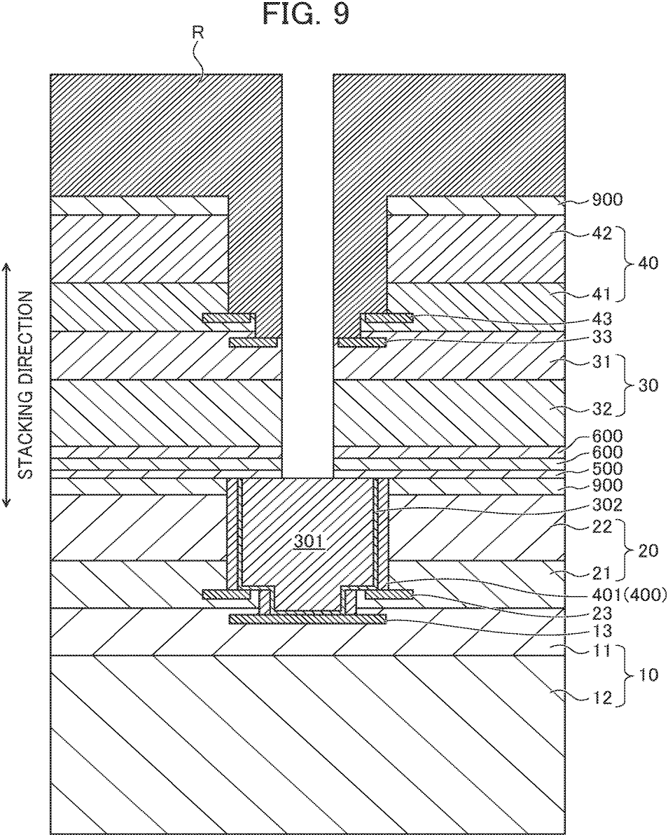

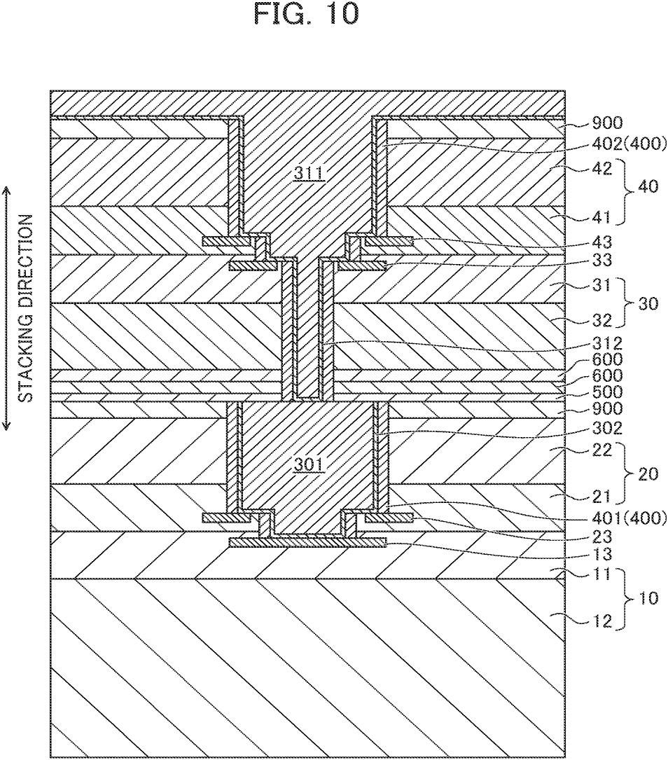

Subsequently, the additional via formation step is executed. In the additional via formation step, the additional via 320 extending in the stacking direction of the additional unit 200 and penetrating the additional unit 200 to contact the reference via 310 is formed. First, in the additional via formation step, a via hole is formed with the position thereof aligned with the position of the electrode 43 of the circuit module 40 on the other end side in the stacking direction, as shown in FIG. 7. Subsequently, in the additional via formation step, a via hole is formed with the position thereof aligned with the position of the through-hole of the electrode 43 of the circuit module 40 on the other end side in the stacking direction, as shown in FIG. 8. Subsequently, in the additional via formation step, a via hole is formed with the position thereof aligned with the position of the through-hole of the electrode 33 of the circuit module 30 on one end side in the stacking direction, as shown in FIG. 9. Subsequently, in the additional via formation step, the additional-side insulating film 402, the additional barrier metal 312, and the additional via body 311 are formed at the position of the via hole, as shown in FIG. 10.

According to the semiconductor device 1 of the first embodiment as described above, the following advantageous effects are produced.

(1) The semiconductor device 1 in which the plurality of circuit modules 10, 20, 30, 40 having the circuit layers 11, 21, 31, 41 and the substrate bodies 12, 22, 32, 42 are stacked on each other includes the reference unit 100 in which at least two circuit modules 10, 20 are stacked on each other with the circuit layers 11, 21 adjacent to each other; the additional unit 200 in which at least two other circuit modules 30, 40 are stacked on each other with the circuit layers 31, 41 adjacent to each other, the additional unit 200 being stacked on the reference unit 100; and the via 300 arranged so as to extend through the reference unit 100 and the additional unit 200 and extending in the stacking direction. The via 300 has the reference via 310 arranged in the reference unit 100, and the additional via 320 arranged in the additional unit 200. The additional via 320 has, at the position at which the additional via 320 contacts the reference via 310, a smaller diameter than the diameter of the reference via 310. With this configuration, expansion of the diameter of the additional via 320 on the other end side in the stacking direction (an additional unit 200 side in the stacking direction) as compared to the reference via 310 can be reduced. Thus, expansion of the region of the additional via 320 in the direction crossing the stacking direction with respect to the area of the circuit module 10, 20, 30, 40 of the additional unit 200 can be reduced.

(2) The additional via 320 has the additional via body 311 penetrating the additional unit 200 in the stacking direction, and the additional-via-320-side barrier metal contacting the outer peripheral surface of the additional via body 311 and contacting the reference via 310. With this configuration, electrical connection between the reference via 310 and the additional via 320 can be improved, and a favorable via can be formed.

(3) The reference via 310 extends from the surface of the reference unit 100 stacked on the additional unit 200 along the stacking direction while the diameter of the reference via 310 is narrowed. With this configuration, the reference via 310 can easily contact the electrodes 13, 23 of the circuit modules 10, 20 forming the reference unit 100.

(4) The tip end portion of the reference via 310 extends to the circuit layer 11 of the circuit module 10 which is different from the other circuit module 20 contacting the additional unit 200. With this configuration, the reference via 310 does not need to penetrate the reference unit 100, and therefore, the reference via 310 can be easily formed.

(5) The method for manufacturing the semiconductor device 1 in which the plurality of circuit modules 10, 20, 30, 40 having the circuit layers 11, 21, 31, 41 and the substrate bodies 12, 22, 32, 42 are stacked on each other includes a reference unit formation step of forming the reference unit 100 in which two circuit modules 10, 20 are stacked on each other with the circuit layers 11, 21 adjacent to each other, a reference via formation step of forming, inside the reference unit 100, the reference via 310 extending in the stacking direction of the reference unit 100, an additional unit formation step of forming the additional unit 200 by stacking two other circuit modules 30, 40 on each other with the circuit layers 31, 41 adjacent to each other, a stacking step of stacking the additional unit 200 on the reference unit 100, and an additional via formation step of forming the additional via 320 extending in the stacking direction of the additional unit 200 and penetrating the additional unit 200 to contact the reference via 310. With this configuration, the semiconductor device 1 can be easily formed. Moreover, expansion of the region of the additional via 320 in the circuit modules 30, 40 can be reduced.

### Second Embodiment

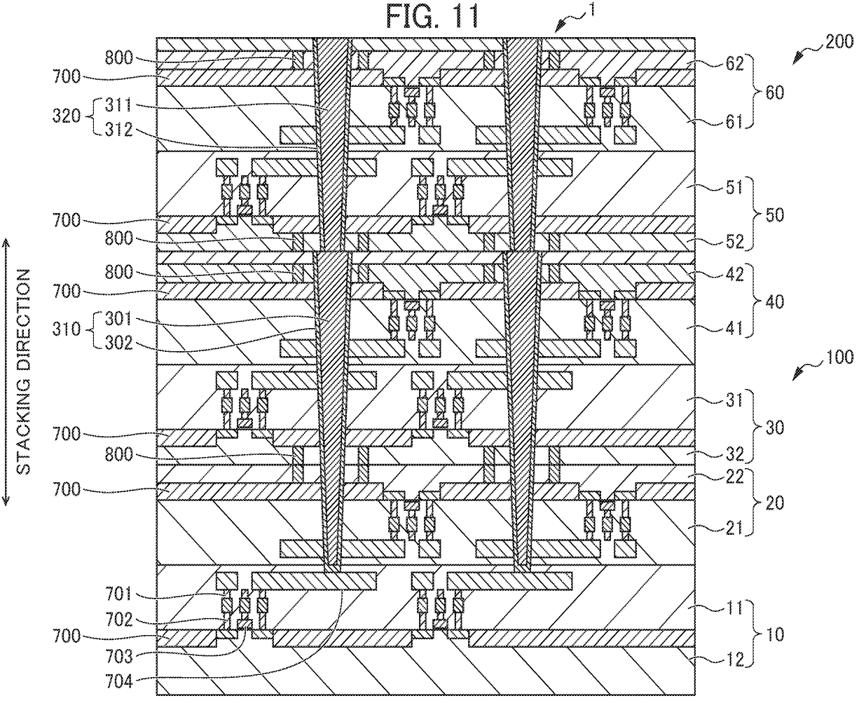

Next, a semiconductor device 1 and a method for manufacturing the semiconductor device 1 according to a second embodiment of the present invention will be described with reference to FIGS. 11 to 16. In the second embodiment, the same reference numerals are used to represent the same configurations and description thereof will be simplified or omitted. The semiconductor device 1 according to the second embodiment is different from that of the first embodiment in that a reference via 310 and an additional via 320 are tapered as shown in FIG. 11. Moreover, the semiconductor device 1 according to the second embodiment is different from that of the first embodiment in that a substrate body 22, 32, 42, 52, 62 of each circuit module 20, 30, 40, 50, 60 surrounds the reference via 310 or the additional via 320 and has dielectric films 800 extending in a stacking direction. Note that in the second embodiment, the reference via 310 is connected to the other-end-side surface of a metal wiring 704 in a circuit layer 11 on one end side in the stacking direction with the reference via 310 and the additional via 320 penetrating metal wirings 704 having no through-hole among through-holes 701, contacts 702, gate electrodes 703, and the metal wirings 704 arranged in the circuit layers 11, 21, 31, 41, 51, 61. At the portions where the reference via 310 or the additional via 320 penetrates the metal wiring 704, a side surface of the reference via 310 or the additional via 320 is electrically connected to the metal wiring 704, and accordingly, the metal wirings 704 are electrically connected to each other. In the second embodiment, the reference via 310 is arranged so as to extend through four circuit modules 10, 20, 30, 40. Moreover, in the second embodiment, the additional via 320 is arranged so as to extend through two circuit modules 50, 60. In the second embodiment, a reference unit 100 includes four circuit modules 10, 20, 30, 40. Moreover, in the second embodiment, an additional unit 200 includes two circuit modules 50, 60. In the second embodiment, two reference vias 310 and two additional vias 320 are arranged, but the present invention is not limited to above.

The dielectric film 800 is, for example, made of silicon dioxide (SiO₂). The dielectric film 800 penetrates, in the stacking direction, the substrate body 22, 32, 42, 52, 62 to a field oxide film 700 arranged in the substrate body 22, 32, 42, 52, 62.

Next, the method for manufacturing the semiconductor device 1 of the second embodiment will be described with reference to FIGS. 11 to 16. The method for manufacturing the semiconductor device 1 according to the second embodiment is different from that of the first embodiment in that a reference unit formation step further includes a first dielectric film formation step of forming the dielectric films 800 in the substrate bodies 22, 32, 42 of the circuit modules 20, 30, 40 of the reference unit 100, the dielectric films 800 being formed so as to surround a position at which the reference via 310 is to be formed. Moreover, the method for manufacturing the semiconductor device 1 according to the second embodiment is different from that of the first embodiment in that an additional unit formation step further includes a second dielectric film formation step of forming the dielectric films 800 in the substrate bodies 52, 62 of the circuit modules 50, 60 of the additional unit 200, the dielectric films 800 being formed so as to surround a position at which the additional via 320 is to be formed. Further, the method for manufacturing the semiconductor device 1 according to the second embodiment is different from that of the first embodiment in that a stacking step includes stacking the reference unit 100 and the additional unit 200 on each other with the positions of the dielectric films 800 aligned with each other in the stacking direction.

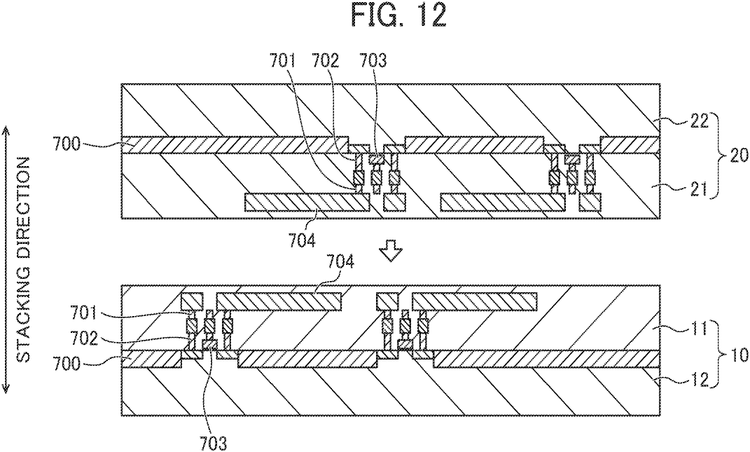

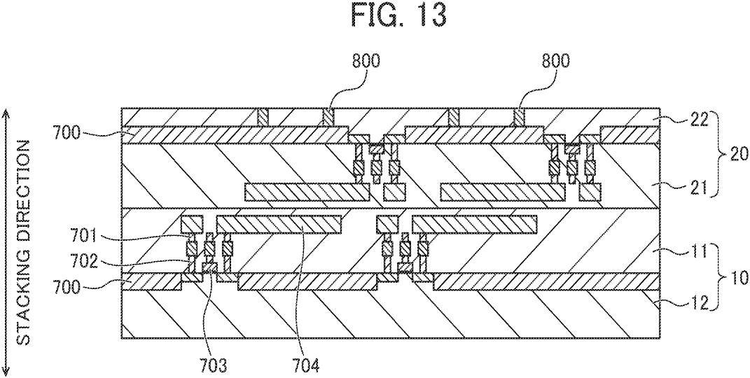

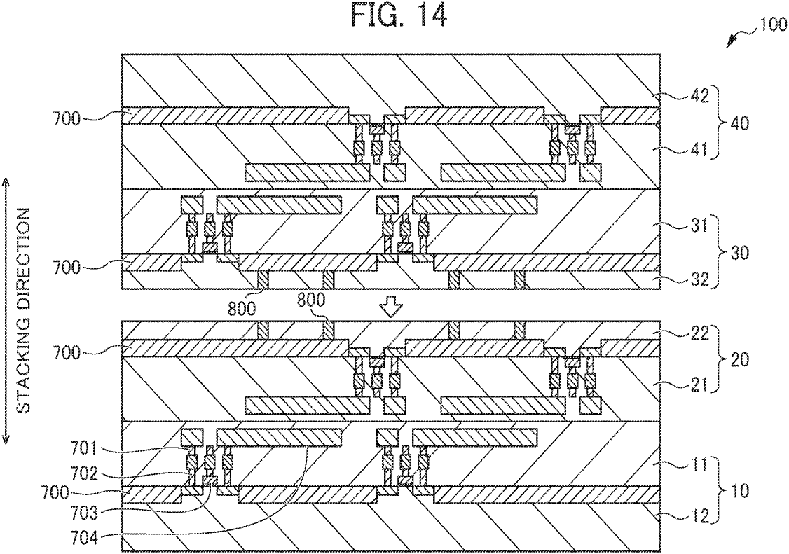

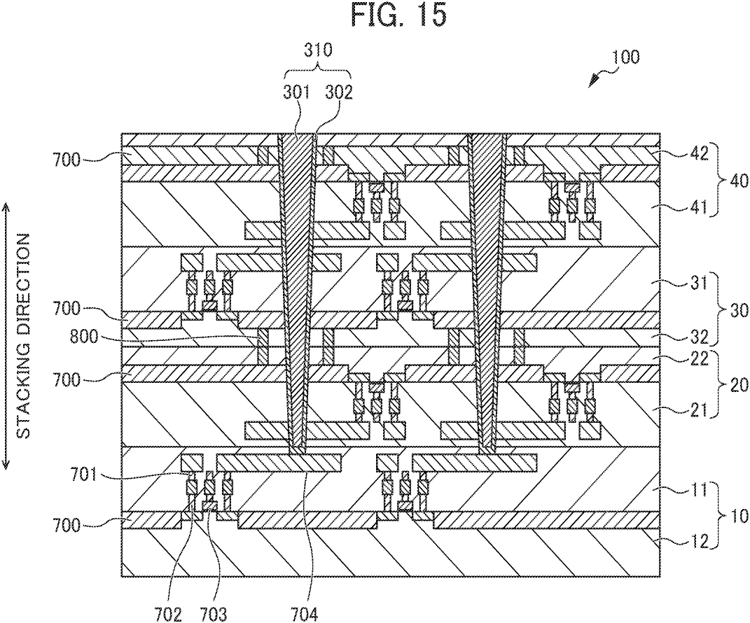

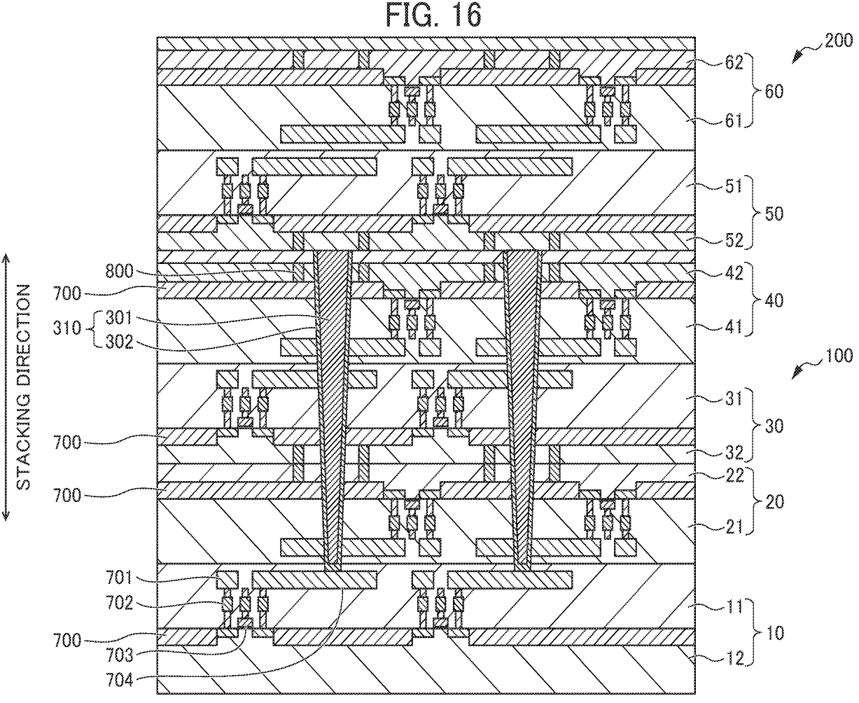

First, as shown in FIG. 12, two circuit modules 10, 20 are stacked on each other. Subsequently, the first dielectric film formation step is executed as shown in FIG. 13. In the first dielectric film formation step, the dielectric film 800 is formed in the substrate body 22 so as to surround the position at which the reference via 310 is to be formed. Subsequently, another pair (the circuit modules 30, 40) is prepared for two circuit modules 10, 20 stacked on each other as shown in FIG. 13, as shown in FIG. 14. The pair of circuit modules 10, 20 and another pair of circuit modules 30, 40 are stacked on each other with the positions of the dielectric films 800 aligned with each other in the stacking direction. Subsequently, a reference via formation step is executed, and the reference unit formation step is executed, as shown in FIG. 15. Subsequently, the additional unit formation step, a second dielectric film formation step of forming the dielectric films 800, and the stacking step are executed as shown in FIG. 16. Then, an additional via formation step is executed as shown in FIG. 11.

According to the semiconductor device 1 and the method for manufacturing the semiconductor device 1 according to the second embodiment as described above, the following advantageous effects are produced.

(8) The substrate body 22, 32, 42, 52, 62 of each circuit module 20, 30, 40, 50, 60 has the dielectric film 800 surrounding the reference via 310 or the additional via 320 and extending along the stacking direction. With this configuration, electrical connection of the reference via 310 or the additional via 320 with the substrate bodies 22, 32, 42, 52, 62 can be reduced. Moreover, the dielectric films 800 are formed only in the substrate bodies 22, 32, 42, 52, 62. Thus, formation of the dielectric film 800 which takes time for machining can be limited to the substrate bodies 22, 32, 42, 52, 62, and the cost can be reduced by a decrease in a process time.

(9) In the method for manufacturing the semiconductor device 1, the reference unit formation step further includes a first dielectric film formation step of forming the dielectric film 800 in the substrate body 22, 32, 42 of each circuit module 20, 30, 40 of the reference unit 100, the dielectric film 800 being formed so as to surround the position at which the reference via 310 is to be formed; and the additional unit formation step further includes a second dielectric film formation step of forming the dielectric film 800 in the substrate body 52, 62 of each circuit module 50, 60 of the additional unit 200, the dielectric film 800 being formed so as to surround the position at which the additional via 320 is to be formed. With this configuration, the reference via 310 and the additional via 320 can be collectively formed through the metal wirings 704 without electrical connection with the substrate bodies 22, 32, 42, 52, 62. Thus, the cost for forming the reference via 310 and the additional via 320 can be reduced.

Each of the preferred embodiments of the semiconductor device 1 and the method for manufacturing the semiconductor device 1 according to the present invention has been described above, but the present invention is not limited to the above-described embodiments and changes can be made as necessary.

For example, in the above-described embodiments, a plurality of additional units 200 may be stacked on the reference unit 100. For example, two additional units 200 may be stacked on the reference unit 100, and in this manner, the semiconductor device 1 may be configured such that six circuit modules are stacked on each other. For example, three additional units 200 may be stacked on the reference unit 100, and in this manner, the semiconductor device 1 may be configured such that eight circuit modules are stacked on each other. The number of circuit modules included in the reference unit 100 or the additional unit 200 is not limited to two or four, and may be an even number equal to or greater than two or four. For example, one or more circuit modules may be stacked on one end side or the other end side of the semiconductor device 1 in the stacking direction.

### EXPLANATION OF REFERENCE NUMERALS

1 Semiconductor Device
10, 20, 30, 40, 50, 60 Circuit Module
11, 21, 31, 41, 51, 61 Circuit Layer
12, 22, 32, 42, 52, 62 Substrate Body
13, 23, 33, 43 Electrode
100 Reference Unit
200 Additional Unit
300 Via
310 Reference Via
320 Additional Via
301 Reference Via Body
302 Reference Barrier Metal
311 Additional Via Body
312 Additional Barrier Metal
400 Insulating Film
500 Etching Stop Layer
600 Cross-Linked Layer
700 Field Oxide Film
704 Metal Wiring
800 Dielectric Film
900 Protective Film

1. A semiconductor device in which a plurality of circuit modules each having a circuit layer and a substrate body are stacked on each other, the semiconductor device comprising:
a reference unit in which at least two circuit modules are stacked on each other with the circuit layers adjacent to each other;
an additional unit in which at least two other circuit modules are stacked on each other with the circuit layers adjacent to each other, the additional unit being stacked on the reference unit; and
a via arranged so as to extend through the reference unit and the additional unit and extending in a stacking direction,
wherein the via has
a reference via arranged in the reference unit, and
an additional via arranged in the additional unit, and
the additional via has, at a position at which the additional via contacts the reference via, a smaller diameter than a diameter of the reference via.

2. The semiconductor device according to claim 1, wherein the additional via has
an additional via body penetrating the additional unit in the stacking direction, and
an additional barrier metal contacting an outer peripheral surface of the additional via body and contacting the reference via.

3. The semiconductor device according to claim 1, wherein the reference via extends from a surface of the reference unit stacked on the additional unit along the stacking direction while the diameter of the reference via is narrowed.

4. The semiconductor device according to claim 1, wherein a tip end portion of the reference via extends to the circuit layer of one of the circuit modules which is different from the other circuit module contacting the additional unit.

5. The semiconductor device according to-any one claim 1, wherein the additional unit includes a plurality of additional units stacked on the reference unit.

6. The semiconductor device according to claim 1, wherein the substrate body of each circuit module has a dielectric film surrounding the reference via or the additional via and extending along the stacking direction.

7. A method for manufacturing a semiconductor device in which a plurality of circuit modules each having a circuit layer and a substrate body are stacked on each other, the method comprising:
a reference unit formation step of forming a reference unit in which at least two circuit modules are stacked on each other with the circuit layers adjacent to each other;
a reference via formation step of forming, inside the reference unit, a reference via extending in a stacking direction of the reference unit;
an additional unit formation step of forming an additional unit by stacking at least two other circuit modules on each other with the circuit layers adjacent to each other;
a stacking step of stacking the additional unit on the reference unit; and
an additional via formation step of forming an additional via extending in a stacking direction of the additional unit and penetrating the additional unit to contact the reference via.

8. The method for manufacturing the semiconductor device according to claim 7, wherein
the reference unit formation step further includes a first dielectric film formation step of forming a dielectric film in the substrate body of each circuit module of the reference unit, the dielectric film being formed so as to surround a position at which the reference via is to be formed, and
the additional unit formation step further includes a second dielectric film formation step of forming a dielectric film in the substrate body of each circuit module of the additional unit, the dielectric film being formed so as to surround a position at which the additional via is to be formed.
